(19) United States
(12) Patent Application Publication
(10) Pub. No.: US 2006/0189071 A1
(43) Pub. Date: Aug. 24, 2006

(54) Integrated circuit capacitor and method of manufacturing same

(76) Inventor: Robert W. Grant, Camden, ME (US)

Correspondence Address: GREENBERG TRAURIG, LLP, ONE INTERNATIONAL PLACE, 20th FL, ATTN: PATENT ADMINISTRATOR, BOSTON, MA, 02110, US

(21) Appl. No.: 11/358,343

(22) Filed: Feb. 21, 2006

Related U.S. Application Data
(60) Provisional application No. 60/655,252, filed on Feb. 22, 2005.

(51) Int. Cl. H01L 21/8242

(52) U.S. Cl. 438/243; 438/247

(57) ABSTRACT

A method for fabricating a capacitor using supercritical CO₂ deposition of metal film layers in a reducing environment from precursors, such as metallo-organic precursors is provided. The method can generate conformal growth on a 3-D cell structure at a relatively high speed, while minimizing the occurrence of oxidation of precursors into Carbon to produce substantially pure metal film layers. A capacitor having a high k dielectric along with associated metal electrodes and contacts on a high aspect ratio 3-D cell structure is also provided.

### RELATED US APPLICATION(S)

The present application claims priority to U.S. Patent Application Ser. No. 60/655,252, filed Feb. 22, 2005, which application is hereby incorporated herein by reference.

### TECHNICAL FIELD

The present invention relates to integrated circuit capacitors and methods of fabricating same using chemical fluid deposition (CFD), and more particularly, a Hydrogen assisted supercritical CO₂ deposition process.

### BACKGROUND ART

New techniques in patterning and deposition have led the way in fulfilling Moore's Law (the historical increase in processor speed), as well as the trend toward lower cost via smaller feature sizes and denser circuitry. Over the history of Large Scale Integrated (LSI) circuits, transistor density has increased dramatically to the extent that as the scale of construction has been halved, the density of transistors has increased by four. In addition, as the density increases, power consumption and electrical current requirements have also increased. In order to isolate transistors from voltage fluctuations resulting from the increased current and lower voltage, measures have been taken, for instance, large (decoupling) capacitors have been designed to isolate the LSI from power supply fluctuations. However, many of the required capacitors (currently planar) have grown in size to a point that they can no longer fit onto the IC chip.

Today, it is common for these capacitors to be mounted off the chip and onto the printed circuit board (FIG. 1). The farther away the decoupling capacitor is mounted from the LSI chip, however, the worse the overall performance of the connecting “wires.” If the decoupling capacitors could be mounted on the chip or even on the intermediate chip mount at low cost, then printed circuit board space and overall cost could be greatly reduced.

Historically, capacitors have been formed on substrates, or more specifically, Silicon wafers, by depositing and patterning thin films of dielectric material and covering the dielectric material with a thin metal film as an electrode. As integrated circuits continue to be made smaller and smaller, the size of the capacitors also need to shrink. However, as sizes shrink to the micron or sub-micron size, the needed capacitance sometimes cannot be achieved within the new small area.

To address this, one approach has been to increase the dielectric property of the insulator. This can been achieved with materials, such as oxides of Hafnium or Tantalum, etc. In particular, if multiple metal oxides, such as high-k dielectrics and metal electrodes can be deposited conformally onto a Silicon wafer, then the space requirements of capacitor structures can be easily reduced, saving hundreds of millions of dollars in production costs. For example, if a Barium Strontium Titanate (BST) dielectric can be effectively used instead of the now common SiO₂ dielectric, a 40 times capacitor area reduction can be achieved. However, although the relative dielectric strength of these materials can help reduce the feature size of the capacitor, such can limit, for instance, the compatibility of the new materials. In addition, current deposition methods cannot provide conformal deposition of multiple oxides on non-planar surfaces, and can include other drawbacks when used to coat high aspect ratio sub-micron feature capacitors.

In particular, conformity and stoichiometry control can act as limiting factors for Chemical Vapor Deposition (CVD). CVD can be used to deposit a dielectric, conductive metal oxide or metal using the decomposition of, for instance, metalorganic precursors in a partial vacuum condition. Since deposition is dependent on precursor concentration arriving to a surface, different deposition rates can result in non-conformal or non-uniform deposition on a non-planar substrate having deep features. For example, in the case of BST deposition using CVD, each of three precursors must be deposited stoichiometrically. Since the three associated precursors have different decomposition temperatures, boiling points, and growth characteristics, maintaining stoichiometry and conformity in a non-planar substrate surface has proven to be difficult. “Bridging” may also occur, eventually closing off the deep feature in the substrate prior to complete coating (FIG. 2). In addition, a CVD deposited film can include up to about 10% Carbon (i.e., CO₂, CO etc.) contamination, which can affect the effectiveness of the resulting capacitor.

In the case of Atomic Layer Deposition (ALD), growth rates can be exceedingly slow and carbon contamination, similar to CVD, may become an issue, even after an Oxygen annealing process. Moreover, with ALD, the precursor is decomposed in Oxygen at reduced pressure to deposit only one atomic monolayer at a time. This process, therefore, can be extremely slow for applications where hundreds of layers are needed, such as the case when depositing film thickness of, for example, 600 Angstroms and only 4 Angstroms (i.e., the thickness of a monolayer) can be deposited at a time. Therefore, even if ALD can provide a substantially conformal deposition method, and precursors were available for metal deposition, it would not address the speed requirements needed.

Sputtering, on the other hand, is a “line of sight” technology, which can be severely limited in non-planar architecture. In particular, droplets of metal are caused to travel across a high vacuum space from a source target toward a substrate. Momentum does not allow the droplets to turn or diffuse into the sides of a deep feature. As a result, this can leave a coating that essentially excludes the sides of the deep feature (FIG. 3). Moreover, if several metals are present in the sputtering target source, there are additional problems related to fractional distillation that can cause incorrect stoichiometry in the deep feature. A resulting film, therefore, may not perform properly.

Accordingly, it would be desirable to provide a method for providing conformal thin film layers, including a high k dielectric layer, on a substrate at a relatively high speed, while minimizing the occurrence of carbon contamination, so that a capacitor with relatively high capacitance density can be fabricated.

### SUMMARY OF THE INVENTION

The present invention provides, in one embodiment, a method for fabricating a capacitor using Hydrogen assisted decomposition of a metalorganic precursor in the presence of supercritical CO₂ (SCCO₂) to deposit a conformal film onto a substrate, for instance, a Silicon substrate.

In accordance with an embodiment, the method includes providing a three dimensional electrically conductive substrate having a surface and a trench extending into the substrate from the surface. Next a first conformal film may be deposited from a mixture of a supercritical gas and a first precursor material onto the surface of the substrate and along surfaces of the trench to subsequently provide a dielectric layer. Thereafter, a second conformal film may be deposited from a solution of a second precursor material onto the first conformal film to subsequently provide a top electrode layer. The deposition of the second conformal layer may be accomplished with or without the use of a supercritical gas and a reaction reagent. In one embodiment, the first conformal layer and the second conformal layer may be oxidized sequentially or simultaneously to form the respective dielectric layer and top electrode layer. Oxidizing the second conformal layer may generate a gas barrier atop the top electrode layer. Alternatively, a third conformal layer may be deposited from a solution of a third precursor material onto the second conformal film to subsequently provide a gas barrier layer. The deposition of the third conformal layer may also be accomplished with or without the use of a supercritical gas and a reaction reagent and may thereafter be oxidized to form the gas barrier layer.

In accordance with another embodiment of the present invention, a method is provided for fabricating a capacitor. The method includes providing a three dimensional substrate having a surface and a trench extending into the substrate from the surface. Next a first conformal film may be deposited from a mixture of a supercritical gas and a first precursor material onto the surface of the substrate and along surfaces of the trench to subsequently provide a bottom electrode layer. Thereafter, a second conformal film may be deposited from a mixture of a supercritical gas a second precursor material onto the first film to subsequently provide a dielectric layer. Then, a third conformal film may be deposited from a mixture of a supercritical gas and a third precursor material onto the second film to subsequently provide a top electrode layer. In one embodiment, after each of the conformal films has been deposited, each may be oxidized to form its respective layer. In certain instances, only some may be oxidized. A fourth conformal film may also be deposited from a mixture of a supercritical gas and a fourth precursor material onto the third film and thereafter oxidized to form a gas barrier layer.

The present invention further provides a capacitor for integrated circuits. The capacitor, in one embodiment, includes a three dimensional electrically conductive substrate having a surface and a trench extending into the substrate from the surface. The three dimensional substrate includes, in an embodiment, a high aspect ratio feature over 5:1 a trench that is sub-micron or nanometer in size. The capacitor also includes a conformal high k dielectric layer positioned on the surface of the substrate and along surfaces of the trench. Positioned on the dielectric layer is a conformal top electrode, and a gas barrier layer on the top electrode. Each of the conformal layers, may be provided with about 2% to about 5% thickness uniformity and substantially without an appreciable amount of Carbon therein. In one embodiment, the three dimensional substrate may include an array of trenches, each provided with a conformal dielectric layer, a conformal top electrode layer, and a conformal gas barrier layer. For such a design, a common top electrode and a common bottom electrode may be provided for the array of trenches.

In a further embodiment, the capacitor may include a three dimensional substrate having a surface and a trench extending from the surface into the substrate. However, instead of having the first layer be the dielectric layer, this capacitor includes a conformal bottom electrode as a first layer, a high k dielectric as a conformal a second layer and a conformal electrode on top of the dielectric. Similar to the above capacitor, each of the conformal layers, may be provided with about 2% to about 5% thickness uniformity and substantially without an appreciable amount of Carbon therein. In addition, three dimensional substrate may include an array of trenches, each provided with a conformal bottom electrode, a conformal dielectric layer, a conformal top electrode layer. A common top electrode and a common bottom electrode may also be provided for the array of trenches. In one embodiment, a gas barrier layer may be provided on the top electrode for each of the trenches in the array to protect against oxide reduction.

### BRIEF DESCRIPTION OF DRAWINGS

FIG. 1 illustrates a prior art design for a capacitor on a printed circuit board.

FIG. 2 illustrates a capacitor fabricated with conventional CVD.

FIG. 3 illustrates a capacitor fabricated with sputtering.

FIG. 4 illustrates a system for Chemical Fluid Deposition using supercritical conditions in accordance with an embodiment of the present invention.

FIG. 5A illustrate a cross-sectional view of a capacitor in accordance with one embodiment of the present invention.

FIG. 5B illustrates a capacitor in accordance with another embodiment of the present invention.

FIG. 5C illustrates a capacitor in accordance with a further embodiment of the present invention.

FIG. 6 illustrates perspective view of a capacitor array in accordance with one embodiment of the present invention.

FIG. 7 is a graph illustrating the range along which the capacitance density may be increased in connection with a capacitor of the present invention.

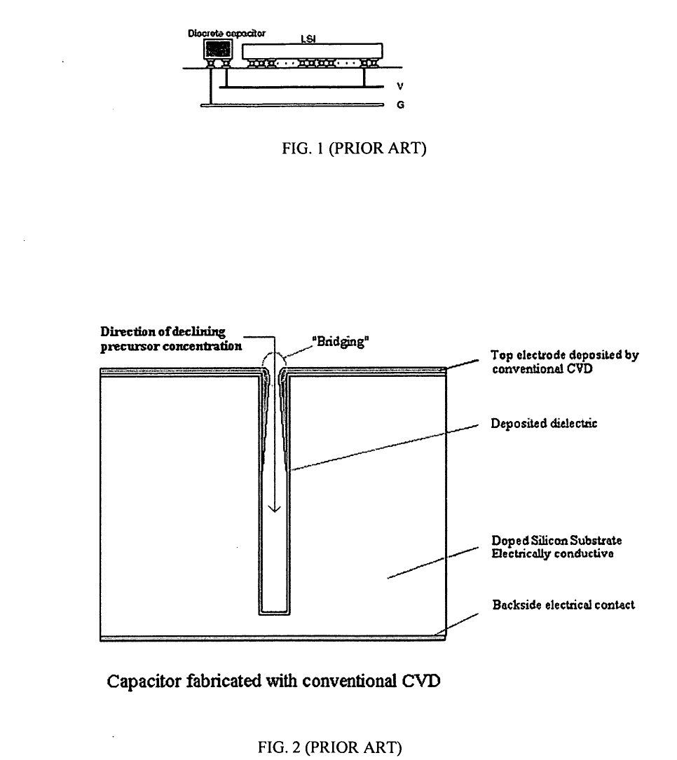

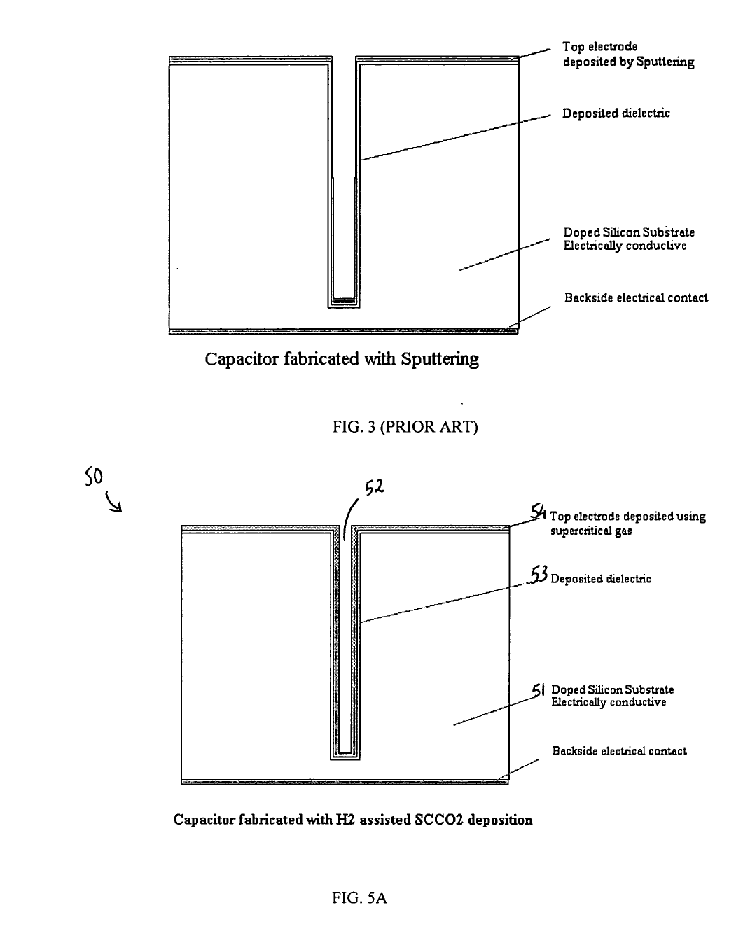

### DESCRIPTION OF SPECIFIC EMBODIMENTS

The present invention provides, in one embodiment, a method for fabricating a capacitor whereby decomposition of a soluble precursor, such as a metallo-organic precursor, in the presence of supercritical solvent (e.g., SCCO₂) may be used to sequentially deposit discrete conformal films or layers onto a substrate, for instance, a silicon substrate. Such an approach, which can generally be referred to as Chemical Fluid Deposition (CFD), permits a growth rate for each film that can be independent of the precursor concentration. The growth rate, however, may be controlled, in one embodiment, by the temperature of the substrate. In addition, since Hydrogen is substantially diffusive and available in over abundance, conformal growth may be possible at rates of up to a micron per minute.

Supercritical deposition, in addition, can provide zero surface tension and a very high Reynolds number compared to CVD, and can also penetrate deep features in the substrate with relative ease. Furthermore, since the decomposition of the precursor minimizes the oxidation of precursor into CO₂, CO etc., the method of the present invention can provide almost no carbonation of the metal film, such as that experienced in CVD or ALD.

In general, Chemical Fluid Deposition (CFD) is a process by which materials (e.g., metals, metal oxides, or organics) may be deposited from a supercritical or near-supercritical solution via chemical reaction of soluble precursors. CFD is generally described in detail in U.S. Pat. No. 5,789,027, which patent is hereby incorporated herein by reference. Desired materials can be deposited on a substrate, such as a silicon wafer, as a high-purity (e.g., better than 99%) thin film (e.g., less than 5 microns). The supercritical fluid employed may be used to transport a precursor material to the substrate surface where a reaction takes place, and to subsequently transport ligand-derived decomposition products away from the substrate to remove potential film impurities. Typically, the precursor in CFD is non-reactive by itself, and a reaction reagent (e.g., a reducing or oxidizing agent) may be mixed into the supercritical solution to initiate the reaction which forms the desired materials. The entire process takes place in solution under supercritical conditions. The process provides a high-purity film at various process temperatures under 250° C., depending on the precursors, solvents, and process pressure used.

Solvents

Solvents that can be used as supercritical fluids are well known in the art and are sometimes referred to as dense gases (Sonntag et al., Introduction to Thermodynamics, Classical and Statistical, 2nd ed., John Wiley & Sons, 1982, p. 40). At temperatures and pressures above certain values for a particular substance (defined as the critical temperature and critical pressure, respectively), saturated liquid and saturated vapor states are identical and the substance is referred to as a supercritical fluid. Solvents that are supercritical fluids are less viscous than liquid solvents by one to two orders of magnitude. In CFD, the low viscosity of the supercritical solvent facilitates improved transport (relative to liquid solvents) of reagent to, and decomposition products away, from the incipient film. Furthermore, many reagents which would be useful in chemical vapor deposition are insoluble or only slightly soluble in various liquids and gases and thus cannot be used in standard CVD. However, the same reagents often exhibit increased solubility in supercritical solvents. Generally, a supercritical solvent can be composed of a single solvent or a mixture of solvents, including for example, a small amount (<5 mol %) of a polar liquid co-solvent such as methanol.

It is important that the reagents are sufficiently soluble in the super-critical solvent to allow homogeneous transport of the reagents. Solubility in a supercritical solvent is generally proportional to the density of the supercritical solvent. Ideal conditions for CFD include a supercritical solvent density of at least 0.2 g/cm³ or a density that is at least one third of the critical density (the density of the fluid at the critical temperature and critical pressure).

The table below lists some examples of solvents along with their respective critical properties. These solvents can be used by themselves or in conjunction with one another or other solvents to form the supercritical solvent in CFD. The table respectively lists the critical temperature, critical pressure, critical volume, molecular weight, and critical density for each of the solvents.

Critical Properties of Selected Solvents

| | T_{c} | P_{c} | V_{c} | Molecular | ρ_{c} |
|---|---|---|---|---|---|
| Solvent | (K) | (atm) | (cm/mol) | Weight | (g/cm³) |
| CO₂ | 304.2 | 72.8 | 94.0 | 44.01 | 0.47 |
| C₂H₆ | 305.4 | 48.2 | 148 | 30.07 | 0.20 |
| C₃H₈ | 369.8 | 41.9 | 203 | 44.10 | 0.22 |
| n-C₄H₁₀ | 425.2 | 37.5 | 255 | 58.12 | 0.23 |
| n-C₅H₁₂ | 469.6 | 33.3 | 304 | 72.15 | 0.24 |
| CH₃—O—CH₃ | 400 | 53.0 | 178 | 46.07 | 0.26 |
| CH₃CH₂OH | 516.2 | 63.0 | 167 | 46.07 | 0.28 |
| H₂O | 647.3 | 12.8 | 65.0 | 18.02 | 0.33 |
| C₂F₆ | 292.8 | 30.4 | 22.4 | 138.01 | 0.61 |

To describe conditions for different supercritical solvents, the terms “reduced temperature,” “reduced pressure,” and “reduced density” may be used. Reduced temperature, with respect to a particular solvent, is temperature (measured in Kelvin) divided by the critical temperature (measured in Kelvin) of the particular solvent, with analogous definitions for pressure and density. For example, at 333 K and 150 atm, the density of CO₂ is 0.60 g/cm³; therefore, with respect to CO₂, the reduced temperature is 1.09, the reduced pressure is 2.06, and the reduced density is 1.28. Many of the properties of supercritical solvents are also exhibited by near-supercritical solvents, which refers to solvents having a reduced temperature and a reduced pressure both greater than 0.8, but not both greater than 1 (in which case the solvent would be supercritical). One set of suitable conditions for CFD include a reduced temperature of the supercritical or near-supercritical solvent of between 0.8 and 1.6 and a critical temperature of the fluid of less than 150° C.

Carbon dioxide (CO₂) is a particularly good choice of solvent for CFD. Its critical temperature (31.1° C.) is close to ambient temperature and thus allows the use of moderate process temperatures (<80° C.). It is also unreactive with most precursors used in CVD and is an ideal media for running reactions between gases and soluble liquids or solid substrates. Other suitable solvents include, for example, ethane or propane, which may be more suitable than CO₂ in certain situations, e.g., when using precursors which can react with CO₂, such as complexes of low-valent metals containing strong electron-donating ligands (e.g., phospines).

Precursors and Reaction Mechanisms

Precursors may be chosen so that they yield the desired material on the substrate surface following reaction with the reaction reagent. Materials can include metals (e.g., Cu, Pt, Pd, and Ti), elemental semiconductors (e.g., Si, Ge, and C), compound semiconductors (e.g., III-V semiconductors such as GaAs and InP, II-VI semiconductors such as CdS, and IV-VI semiconductors such as PbS), oxides (e.g., SiO₂ and TiO₂), or mixed metal or mixed metal oxides (e.g., a superconducting mixture such as Y—Ba—Cu—O). Organometallic compounds and metallo-organic complexes are an important source of metal-containing reagents and are particularly useful as precursors for CFD. In contrast, most inorganic metal-containing salts are ionic and relatively insoluble, even in supercritical fluids that include polar modifiers such as methanol.

Some examples of useful precursors for CFD include metallo-organic complexes containing the following classes of ligands: beta-diketonates (e.g., Cu(hfac)₂ or Pd(hfac)₂, where hfac is an abbreviation for 1,1,1,5,5,5-hexafluoroacetylacetonate), alkyls (e.g., Zn(ethyl)₂ or dimethylcyclooctadiene platinum (CODPtMe₂)), allyls (e.g. bis(allyl)zinc or W(π⁴-allyl)₄), dienes (e.g., CODPtMe₂), or metallocenes (e.g., Ti(π⁵-C₅H₅)₂ or Ni(π⁵-C₅H₅)₂). For a list of additional potential precursors see, for example, M. J. Hampden-Smith and T. T. Kodas, Chem. Vap. Deposition, 1:8 (1995).

It should be noted that precursor selection for CVD is limited to stable organometallic compounds that exhibit high vapor pressure at temperatures below their thermal decomposition temperature. This limits the number of potential precursors. On the other hand, CFD obviates the requirement of precursor volatility, and instead replaces it with a much less demanding requirement of precursor solubility in a supercritical fluid.

Any reaction yielding the desired material from the precursor can be used in CFD. However, low process temperatures (e.g., less than 250° C., 200° C., 150° C., or 100° C.) and relatively high fluid densities (e.g., greater than 0.2 g/cm³) in the vicinity of the substrate are important features of CFD. If the substrate temperature is too high, the density of the fluid in the vicinity of the substrate approaches the density of a gas, and the benefits of the solution-based process may be lost. In addition, a high substrate temperature can promote deleterious fragmentation and other side-reactions that lead to film contamination. Therefore a reaction reagent, rather than thermal activation, may be used in CFD to initiate the reaction that yields the desired material from the precursor.

For example, the reaction can involve reduction of the precursor (e.g., by using H₂ or H₂S as a reducing agent), oxidation of the precursor (e.g., by using O₂ or N₂O as an oxidizing agent), or hydrolysis of the precursor (i.e., adding H₂O). An example of an oxidation reaction in CFD is the use of O₂ (the reaction reagent) to oxidize a zirconium beta-diketonate (the precursor) to produce a metal thin film of ZrO₂. An example of a hydrolysis reaction in CFD is water (the reaction reagent) reacting with a metal alkoxide (the precursor), such as titanium tetraisopropoxide (TTIP), to produce a metal oxide thin film, such as TiO₂. The reaction can also be initiated by optical radiation (e.g., photolysis by ultraviolet light). In this case, photons from the optical radiation can be the reaction reagent.

In this supercritical processing approach, chemical selectivity at the substrate can be enhanced by a temperature gradient established between the substrate and the supercritical solution. For example, a gradient of 40° C. to 250° C. or 80° C. to 150° C. can be beneficial. However, to maintain the benefits of CFD, the temperature of the substrate measured in Kelvin, divided by the average temperature of the supercritical solution measured in Kelvin, may typically be maintained between 0.8 and 1.7.

In some cases, the supercritical fluid can participate in the reaction. For example, in a supercritical solution including N₂O as a solvent and metal precursors such as organometallic compounds, N₂O can serve as an oxidizing agent for the metal precursors yielding metal oxides as the desired material. In most cases, however, the solvent in the supercritical fluid is chemically inert.

System for Deposition

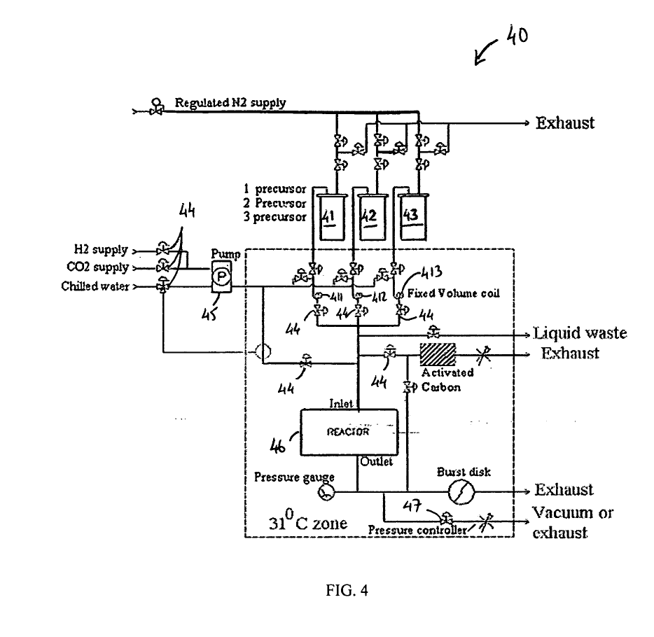

Looking now at FIG. 4, there is illustrated, in accordance with one embodiment of the present invention, a system 40 for implementing a CFD deposition protocol, for example, a hydrogen assisted supercritical deposition protocol. As shown in FIG. 4, vessels 41, 42, and 43 may each be provided with a distinct precursor for subsequent deposition of an individual discrete film layer onto a substrate, such as a silicon substrate situated in a reactor 46. These precursors, examples of which are provided above, may be provided in liquid form and may, in an embodiment, be slightly pressurized by, for instance, N₂ gas. Since the deposition process employed by the present invention involves the use of supercritical gases, such as CO₂, high pressure valves 44 which can withstand the pressures of supercritical gases may be used throughout the system 40.

To initiate the deposition process, a micro-volume of a precursor, such as that from vessel 41, may be generated within a coil of small tubing 411. It should be appreciated that a micro-volume each of the precursors from each of vessels 42 and 43 may also be generated within coils 412 and 413 respectively for sequential deposition of subsequent thin film layers on the substrate.

Next, to generate the supercritical gas, a solvent, such as CO₂, may be supplied to a pump 45 in either liquid form, or as a high-pressure gas. In the case the solvent is to be supplied as a gas, the solvent may subsequently be condensed to a liquid. The liquid solvent may next be pressurized to supercritical pressure, for CO₂ it is about 1100 PSI and can be higher. It should be noted that whether the solvent is supplied as a gas or a liquid, a reaction agent such as Hydrogen (e.g., H₂ gas) may be introduced on the low-pressure or high-pressure side of the pump 45 and allowed to mix with the solvent to assist in the supercritical processing of the precursor for subsequent deposition. Once reaching pressure for supercritical gas conditions, heat may be added to bring this gas mixture up to supercritical temperature. In the case of supercritical CO₂, the temperature is about 31° C.

Upon reaching supercritical pressure and temperature, the supercritical gases (e.g., CO₂ and H₂) may be flushed through the coils 411, 412, and 413 containing the respective micro-volumes to substantially dissolve the precursor material. The supercritical gas and precursor mixture may be then directed toward a reactor 46, which may contain or be partially filled with a supercritical gas, such as CO₂. It should be appreciated that the system 40, in one embodiment, may be conditioned to the temperature of the supercritical gas, so as to minimize shock and preserve the supercritical condition for the process. In this example, since about 1100 PSI is employed in connection with CO₂, the system 40 may be maintained at about 31° C. to preserve the supercritical condition. The system 40, in an embodiment, may also be provided with, for instance, pressure gauges and metal burst discs to monitor and maintain the safety of the system 40.

Once the supercritical gas and precursor mixture has been introduced and stabilized within the reactor 46, the temperature of a platform upon which the substrate sits within the reactor 46 may be brought up to that similar to the processing temperature. In the case of SCCO₂ and, for instance, a Platinum precursor, the platform may be heated to about 60° C. It should be appreciated that since, for example, Hydrogen assisted SCCO₂ deposition rates may be zero order dependent on concentration, the temperature may be used as a primary control for the deposition rate. To the extent that other precursors may be used, the temperature of the platform may be varied accordingly up to about 200° C.

After the deposition reaches a desired thickness on the substrate, a high pressure valve 47 downstream of the reactor 46 may be opened, so that substantially all the gases (e.g., SCCO₂, H₂) and solutes (e.g., precursor ligands, unused precursor) can leave the system 40. To facilitate removal of the gases and solutes from the reactor 46 and the precursor paths, additional amounts of SCCO₂ may be used to flush the system 40 since there is substantially good solubility with the gases and the solutes. In one embodiment, a cleaning additive may be used with SCCO₂ to enhance the flushing and cleaning process. A by-product trap, such as an activated carbon canister, may also be provided for use in connection with the cleaning process.

Once the first layer has been deposited onto the surface of the substrate, subsequent thin film layers may be sequentially deposited atop the first layer on the substrate by repeating the steps disclosed above using, for instance, the precursors from vessel 412 and 413 respectively.

Once the deposition process has completed, reactor 46 may be allowed to depressurize toward a transfer pressure. The transfer pressure may be positive or negative (vacuum) depending on the situation. Transfer pressure, in one embodiment, can be achieved through the use of a downstream pressure controller 47 or the use of a connected vent line to the handler (not shown).

Capacitor Fabrication

As noted above, to continue at the present pace of miniaturization of the capacitor, the present invention contemplates providing, in one embodiment, a capacitor having a high k dielectric along with associated metal electrodes and contacts on a high aspect ratio three dimensional (3-D) cell structure (i.e., substrate). Such a capacitor may be fabricated, in an embodiment, by employing the system 40 described above using Hydrogen assisted supercritical CO₂ deposition of metal film layers in a reducing environment from precursors, such as metallo-organic precursors. In particular, the system 40 and the supercritical CO₂ deposition process can generate, in an embodiment, conformal growth on a 3-D cell structure at a relatively high speed, while minimizing the occurrence of oxidation of precursors into CO₂, CO etc. to produce substantially pure metal film layers without carbonation or oxide interfaces.

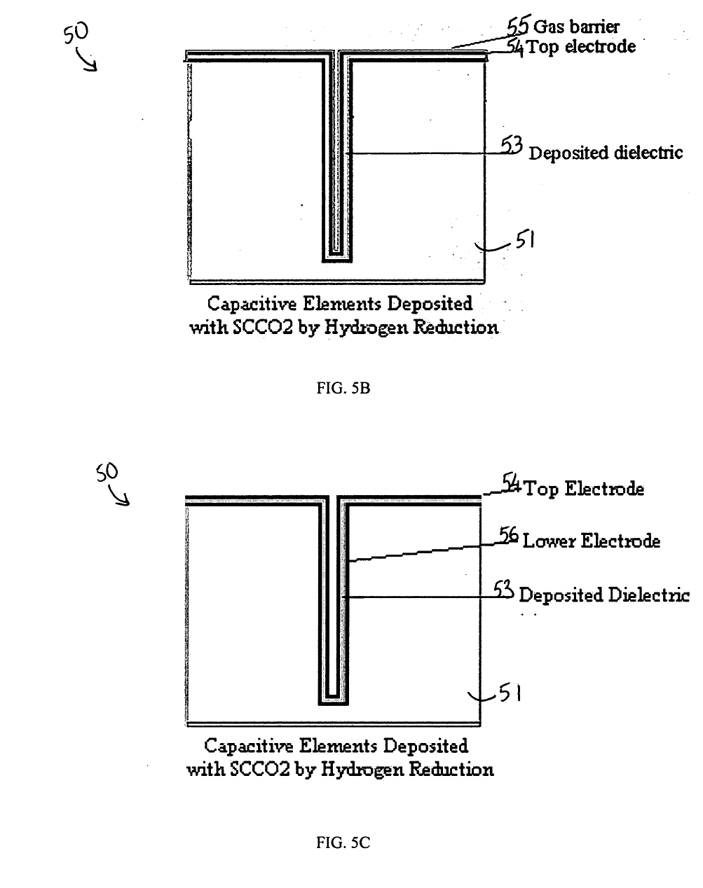

Referring now to FIG. 5A, a capacitor 50 may be fabricated in accordance with an embodiment of the present invention. Initially, an electrically conductive 3-D cell structure or substrate 51, such as a doped Silicon substrate, may be provided. As illustrated in FIG. 5A, such a substrate may include a trench or deep hole 52, typically sub-micron or nanometer in size (e.g., about 0.25 micron or greater), to provide a three dimensional structure needed for the high aspect ratio features. In one embodiment the high aspect ratio may be over 5:1 and may range from about 5:1 to about 100:1 depth to width.

Next, a first thin metal film 53 may be conformally deposited onto the surface of substrate 51, including within the trench 52 and along its sidewalls, using Hydrogen assisted SCCO₂ deposition of a precursor, such as a metallo-organic precursor or one of the precursors disclosed above, in a reducing environment. This thin metal film 53 may thereafter be oxidized by furnace treatment or by rapid thermal anneal (RTA) in O₂ at a temperature ranging from about 300° C. to about 600° C. depending on the precursor used to form a dielectric layer. In one embodiment, this thin metal layer 53 (i.e., the dielectric layer) can be a high k dielectric if the precursor used includes, for instance, SrTa, Hf, Ta, Al, or HfSi. Of course, other related metals or metal alloys, such as Pb, Zr, Ti, BiLaTi, SrTaNiNb, SrTaBi, BiTi, PbZrTi or SrTi, or a combination thereof may be used. It should be noted that the annealing process can provide the dielectric layer 53 with adhesive characteristics, compatible grain size, and compatible thermal expansion to that of subsequent layers.

In providing capacitor 50 with high aspect ratio to achieve relatively high capacitance, the total thickness of the metal film layers thereon, in an embodiment, may range from about 50 Angstroms to about 5000 Angstroms or more on the substrate 51, as well as within trench 52, depending on the depth and width of the trench 52. In an embodiment wherein the trench 52 has a width of about 0.25 micron, the first or starting thin layer 53 on the surface of substrate 51 may be provided with a thickness ranging from about 10 Angstroms to about 1000 Angstroms. Subsequent layers may also be provided with a similar or different thickness range, depending on the materials. For instance, the thickness range may be from about 50 to about 500 Angstroms for dielectrics, and from about 500 to about 5000 Angstroms for metal electrodes. It should be noted that in the Hydrogen assisted SCCO₂ process employed herein, the desired thickness for the first thin layer 53 can be achieved relatively quickly, for instance, in about a minute or less.

After the first thin metal layer 53 (i.e., dielectric layer) has been formed, a second thin metal film 54 can be deposited atop the first thin metal layer 53 using a precursor metal, or one whose oxide is conductive, examples of which include, Ru, Ir, Pt, Al, Ag, Au, Pd, Cu, AlCu, AlCuSi, etc., to complete the formed capacitor 50. The second thin metal film 54 may subsequently be oxidized or annealed by RTA in O₂ at a temperature ranging from about 300° C. to about 600° C. depending on the precursor used to form a top electrode layer. In the case of Ru and Ir for instance, the oxygen annealing process can provide the top electrode layer 54 with a conductive oxide which can also act as a gas barrier. The oxygen annealing process can also provide the top electrode layer 54 with adhesion characteristics, compatible or desired grain size, and compatible thermal expansion, among others, similar to that of the dielectric layer 53.

It should be noted that if electrode layer 54 is composed of a noble metal, then no oxidation takes place, but the layer can permit oxygen to permeate therethrough to oxidize the other layers.

In an alternate embodiment, the first thin metal film 53 and the second thin metal film 54 can initially be deposited in sequence. Thereafter, a single oxidizing step by way of, for instance, a furnace treatment or RTA in O₂, can be performed to simultaneously oxidize the first thin metal film to form the dielectric layer 53 and the second thin metal film to form the conductive top electrode 54. Although described in connection with the Hydrogen assisted SCCO₂ deposition process, it should be noted that the deposition of the film for the top electrode layer 54 may be carried out with or without the Hydrogen assisted SCCO₂ deposition process.

In another embodiment, looking now at FIG. 5B, a barrier layer 55 may be deposited atop the top electrode layer 54 to protect against oxide reduction, for instance, due to subsequent interconnect processing. In particular, a precursor metal or alloy, or one whose oxide can act as a barrier to a gas (e.g., Hydrogen or Oxygen), or a barrier to a semiconductor contaminant element, such as Na, Ca, or Ru, may be used to form a third thin film on the top electrode layer 54. Examples of such metal, alloy or oxides thereof include Ru, Ir, Al, Cu, Pd, Au, Ag, Pt or a combination thereof. Once deposited, this third thin metal film may subsequently be oxidized by furnace treatment or RTA in O₂ at a temperature ranging from about 300° C. to about 600° C., depending on the precursor used, to form the barrier layer 55. The oxygen annealing process can also provide the barrier layer 55 with adhesion characteristics, compatible grain size, and compatible thermal expansion to that of the other layers. Moreover, although described in connection with the Hydrogen assisted SCCO₂ deposition process, it should be noted that the deposition of the barrier layer 55 may be carried out with or without the Hydrogen assisted SCCO₂ deposition process. Furthermore, although not discussed, it should be noted that the barrier layer 55 is deposited only after patterning has taken place on the electrode layer 54.

Referring now to FIG. 5C, to the extent desired, a bottom electrode layer 56 may be deposited on to the surface of substrate 51 prior to deposition of the film for the dielectric layer 53. Deposition of a thin metal film for the bottom electrode layer 56, in one embodiment, may be implemented in a similar manner, using similar choices for a precursor material, and oxidized in substantially the same way as that carried out with the top electrode layer 54. In addition, a barrier layer may be deposited onto the lower electrode layer 56 prior to deposition of the dielectric layer 53. In certain instances, it may also be advantageous to utilize a metal oxide adhesion layer, for instance, Titanium oxide, to enhance adhesion of the lower metal electrode to the substrate 51. In providing a bottom electrode layer 56, the dielectric layer 53, as shown in FIG. 5C, may be sandwiched between the top electrode layer 54 and the bottom electrode layer 56. In such an embodiment, substrate 51 may need not be electrically conductive, as the bottom electrode layer 56 and the top electrode layer 54 can provide the necessary conductive loop (i.e., circuit) for the capacitor 50. Moreover, the substrate 51 may be dielectric, such as SiO₂, to minimize unwanted capacitance underneath the lower electrode layer 56.

The resulting capacitor structure for integrated circuits (Decoupling, Tuning, DRAM, ROM, SRAM, FeRAM etc.) may, in one embodiment, be provided with high aspect ratio feature over 5:1, e.g., ranging from at about 5:1 to about 100:1 depth to width, and may include conformally deposited thin layers, including a high k dielectric layer, that are substantially pure in content. Each thin film layer, in an embodiment, can be provided with about 2% to about 5% thickness uniformity and substantially without an appreciable amount of Carbon.

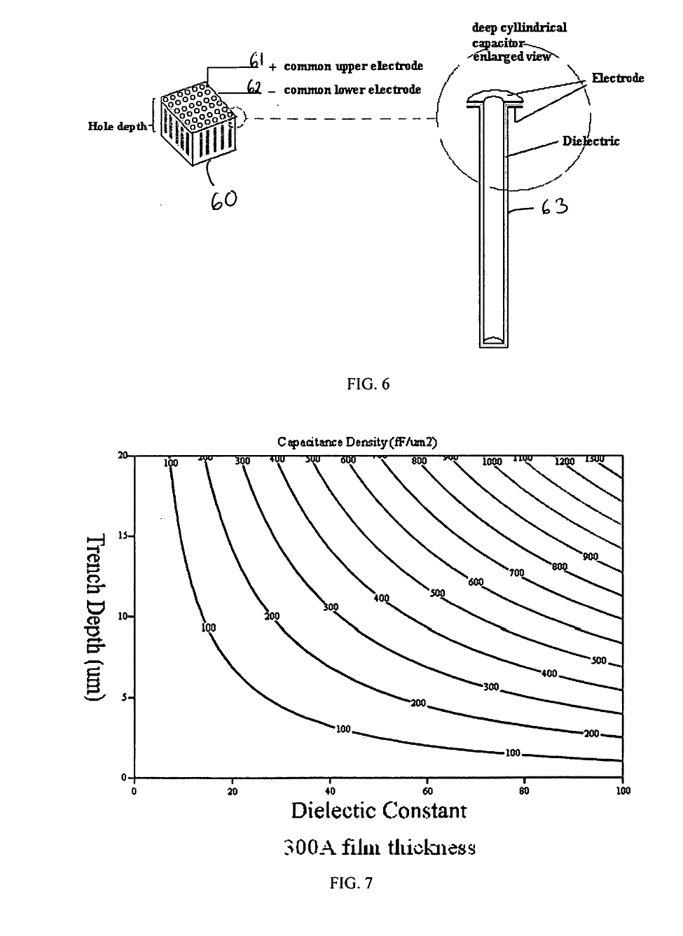

Although shown as a single 3-D capacitor 50, it should be appreciated that a 3-D array, such as capacitor array 60 shown in FIG. 6, may be fabricated in connection with the Hydrogen assisted SCCO₂ deposition process employed by the present invention. The array 60, in one embodiment, may be provided with a common top electrode 61 and a common bottom electrode 62 rather than individual top and bottom electrodes for each capacitor 63 in the array 60. With such a 3-D array, capacitor 60 can exhibit, in one embodiment, an increase in capacitance density up to about 1500 times (see FIG. 7). Alternatively, capacitor array 60 may be made approximately 150 times smaller than current high k designs, while maintaining similar capacitance density to that of current designs. Such characteristics can easily provide a solution to IC chip isolation problem and enable implementation of higher-speed logic, microprocessor, mobile and memory LSI circuits, among others.

The foregoing has outlined, in general, certain aspect of the invention and is to serve as an aid to better understanding the more complete detailed description which is to follow. In reference to such, there is to be a clear understanding that the present invention is not limited to the method or detail of construction, fabrication, material, or application of use described and illustrated herein. Any other variation of fabrication, use, or application should be considered apparent as an alternative embodiment of the present invention.

What is claimed is:

1. A method for fabricating a capacitor, the method comprising:
providing a three dimensional electrically conductive substrate having a surface and a trench extending into the substrate from the surface;
depositing, onto the surface of the substrate and along surfaces of the trench, a first conformal film from a mixture of a supercritical gas and a first precursor material to subsequently provide a dielectric layer;
depositing, onto the first conformal film, a second conformal film from a solution of second precursor material to subsequently provide a top electrode layer; and
forming a gas barrier atop the top electrode layer.

2. A method as set forth in claim 1, wherein, in the step of providing, the three dimensional substrate includes a high aspect ratio feature over 5:1.

3. A method as set forth in claim 1, wherein the step of depositing the first conformal film onto the surface of the substrate includes oxidizing the first conformal film to provide the dielectric layer.

4. A method as set forth in claim 1, wherein, in the step of depositing the first conformal film, the supercritical gas includes CO₂ and the first precursor includes one of Hf, HfSi, Ta, Al, Bi, Pb, Zr, Ti, SrTa, SrTi, BiTi, BiSrTa, BiLaTi, PbZrTi, SrTaNiNb, or a combination thereof.

5. A method as set forth in claim 1, wherein the step of depositing the second conformal film includes oxidizing the second conformal film to provide the top electrode layer.

6. A method as set forth in claim 5, wherein the step forming the gas barrier results from oxidizing the second conformal film.

7. A method as set forth in claim 1, wherein, in the step of depositing the second conformal film, the solution of a second precursor includes one of Ru, Ir, Pt, Al, Ag, Au, Pd, Cu, AlCu, AlCuSi, or a combination thereof.

8. A method as set forth in claim 1, wherein the step of depositing a second conformal film employs a mixture of a supercritical gas and reaction reagent for the second precursor material.

9. A method as set forth in claim 8, wherein, in the step of depositing the second conformal film, the supercritical gas includes CO₂ and the solution of a second precursor includes one of Ru, Ir, Pt, Al, Ag, Au, Pd, Cu, AlCu, AlCuSi, or a combination thereof.

10. A method as set forth in claim 8, wherein the step of depositing the second conformal film includes oxidizing the second conformal film to provide the top electrode layer.

11. A method as set forth in claim 10, wherein the step forming the gas barrier results from oxidizing the second conformal film.

12. A method as set forth in claim 1, further including:
simultaneously oxidizing the first conformal film and the second conformal film to form the dielectric layer and the top electrode layer thereon.

13. A method as set forth in claim 1, wherein the step of forming the gas barrier includes:
depositing, onto the top electrode layer, a third conformal film from a solution of third precursor material to subsequently provide a gas barrier; and
oxidizing the third conformal film to form the gas barrier.

14. A method as set forth in claim 13, wherein the step of depositing the third conformal film employs a mixture of a supercritical gas and a reaction reagent for the third precursor material.

15. A method as set forth in claim 13, wherein, in the step of depositing the third conformal film, the supercritical gas includes CO₂ and the second precursor includes one of Ru, Ir, Pt, Al, Ag, Au, Pd, Cu or a combination thereof.

16. A method for fabricating a capacitor, the method comprising:
providing a three dimensional substrate having a surface and a trench extending into the substrate from the surface;
depositing, onto the surface of the substrate and along surfaces of the trench, a first conformal film from a mixture of a supercritical gas and a first precursor material to subsequently provide a bottom electrode;
depositing, onto the first conformal film, a second conformal film from a mixture of a supercritical gas and a second precursor material to subsequently provide a dielectric layer; and
depositing, onto the second conformal film, a third conformal film from a mixture of a supercritical gas and a third precursor material to subsequently provide a top electrode layer.

17. A method as set forth in claim 16, wherein, in the step of providing, the three dimensional substrate includes a high aspect ratio feature over 5:1.

18. A method as set forth in claim 16, wherein the step of depositing the first conformal film onto the surface of the substrate includes oxidizing the first conformal film to provide the bottom electrode layer.

19. A method as set forth in claim 16, wherein, in the step of depositing the first conformal film, the supercritical gas includes CO₂ and the first precursor includes one Ru, Ir, Pt, Al, Ag, Au, Pd, Cu, AlCu, AlCuSi, or a combination thereof.

20. A method as set forth in claim 16, wherein the step of depositing the second conformal film includes oxidizing the second conformal film to provide the dielectric layer.

21. A method as set forth in claim 16, wherein, in the step of depositing the second conformal film, the supercritical gas includes CO₂ and the second precursor includes one of Hf, HfSi, Ta, Al, Bi, Pb, Zr, Ti, SrTa, SrTi, BiTi, BiSrTa, BiLaTi, PbZrTi, SrTaNiNb, or a combination thereof.

22. A method as set forth in claim 16, wherein the step of depositing the third conformal film includes oxidizing the third conformal film to provide the top electrode layer.

23. A method as set forth in claim 22, wherein the step of oxidizing generates a gas barrier atop the top electrode layer.

24. A method as set forth in claim 16, wherein, in the step of depositing the third conformal film, the supercritical gas includes CO₂ and the third precursor includes one of Ru, Ir, Pt, Al, Ag, Au, Pd, Cu, AlCu, AlCuSi, or a combination thereof.

25. A method as set forth in claim 16, further including:
simultaneously oxidizing the first conformal film, the second conformal film, and the third conformal film to form the bottom electrode layer, the dielectric layer and the top electrode layer respectively.

26. A method as set forth in claim 16, further including:
depositing, onto the top electrode layer, a fourth conformal film from a mixture of a supercritical gas and a fourth precursor material to subsequently provide a gas barrier; and
oxidizing the fourth conformal film to form the gas barrier.

27. A method as set forth in claim 26, wherein, in the step of depositing the fourth conformal film, the supercritical gas includes CO₂ and the fourth precursor includes one of Ru, Ir, Pt, Al, Ag, Au, Pd, Cu, or a combination thereof.

28. A capacitor comprising:
a three dimensional electrically conductive substrate having a surface and a trench extending into the substrate from the surface;
a conformal dielectric layer positioned on the surface of the substrate and along surfaces of the trench;
a conformal top electrode positioned on the dielectric layer; and
a conformal gas barrier layer positioned on the top electrode.

29. A capacitor as set forth in claim 28, wherein the three dimensional substrate includes a high aspect ratio feature over 5:1.

30. A capacitor as set forth in claim 28, wherein the trench is sub-micron or nanometer in size.

31. A capacitor as set forth in claim 28, wherein the dielectric layer is generated from a high k material.

32. A capacitor as set forth in claim 31, wherein the high k material includes one of Hf, HfSi, Ta, Al, Bi, Pb, Zr, Ti, SrTa, SrTi, BiTi, BiSrTa, BiLaTi, PbZrTi, SrTaNiNb, or a combination thereof.

33. A capacitor as set forth in claim 28, wherein the top electrode and the gas barrier layer are made from a material including a metal, metal alloy, superconducting mixture or a combination thereof.

34. A capacitor as set forth in claim 33, wherein the material includes Ru, Ir, Pt, Al, Ag, Au, Pd, Cu, AlCu, AlCuSi, or a combination thereof.

35. A capacitor as set forth in claim 28, wherein each of the conformal layers is provided with about 2% to about 5% thickness uniformity.

36. A capacitor as set forth in claim 28, wherein each of the conformal layers is deposited substantially without an appreciable amount of Carbon therein.

37. A capacitor as set forth in claim 28 wherein the three dimensional substrate includes an array of trenches, each provided with a conformal dielectric layer, a conformal top electrode layer, and a conformal gas barrier layer.

38. A capacitor as set forth in claim 28, wherein the array further includes a common top electrode and a common bottom electrode.

39. A capacitor comprising:
a three dimensional substrate having a surface and a trench extending from the surface into the substrate;
a conformal bottom electrode positioned on the surface of the substrate and along surfaces of the trench;
a conformal dielectric layer positioned on the bottom electrode; and
a conformal top electrode positioned on the dielectric layer.

40. A capacitor as set forth in claim 39, wherein the three dimensional substrate includes a high aspect ratio feature over 5:1.

41. A capacitor as set forth in claim 39, wherein the trench is sub-micron or nanometer in size.

42. A capacitor as set forth in claim 39, wherein the bottom electrode layer and the top electrode layer are made from a material including a metal, metal alloy, superconducting mixture or a combination thereof.

43. A capacitor as set forth in claim 42, wherein the materials of Ru, Ir, Pt, Al, Ag, Au, Pd, Cu, AlCu, AlCuSi, or a combination thereof.

44. A capacitor as set forth in claim 39, wherein the dielectric layer is generated from a high k material.

45. A capacitor as set forth in claim 44, wherein the high k material includes one of Hf, HfSi, Ta, Al, Bi, Pb, Zr, Ti, SrTa, SrTi, BiTi, BiSrTa, BiLaTi, PbZrTi, SrTaNiNb, or a combination thereof.

46. A capacitor as set forth in claim 39, further including a gas barrier positioned on the top electrode layer.

47. A capacitor as set forth in claim 46, wherein the gas barrier layer is made from a material including a metal, metal alloy, superconducting mixture or a combination thereof.

48. A capacitor as set forth in claim 47, wherein the material of Ru, Ir, Pt, Al, Ag, Au, Pd, Cu, or a combination thereof.

49. A capacitor as set forth in claim 46, wherein each of the conformal layers is provided with about 2% to about 5% thickness uniformity.

50. A capacitor as set forth in claim 46, wherein each of the conformal layers is deposited substantially without an appreciable amount of Carbon therein.

51. A capacitor as set forth in claim 39, wherein the three dimensional substrate includes an array of trenches, each provided with a conformal dielectric layer, a conformal top electrode layer, and a conformal gas barrier layer.

52. A capacitor as set forth in claim 51, wherein the array further includes a common top electrode and a common bottom electrode.

53. A capacitor as set forth in claim 51, wherein the array includes a gas barrier layer within each of the trenches.
